(19) United States
(12) Patent Application Publication
(10) Pub. No.: US 2024/0083428 A1
(43) Pub. Date: Mar. 14, 2024

(54) REINFORCEMENT LEARNING ALGORITHM-BASED PREDICTIVE CONTROL METHOD FOR LATERAL AND LONGITUDINAL COUPLED VEHICLE FORMATION

(71) Applicant: Jilin University, Changchun (CN)

(72) Inventors: Shuyou YU, Changchun (CN); Yunyong LI, Changchun (CN); Yangyang FENG, Changchun (CN); Encong SHENG, Changchun (CN); Baojun LIN, Changchun (CN); Hong CHEN, Changchun (CN)

(73) Assignee: Jilin University, Changchun (CN)

(21) Appl. No.: 18/221,405

(22) Filed: Jul. 13, 2023

(30) Foreign Application Priority Data
Sep. 7, 2022 (CN) 202211087600.7

(51) Int. Cl. B60W 30/12; G06N 3/092

(52) U.S. Cl. CPC B60W 30/12; G06N 3/092; B60W 2520/10; B60W 2520/12; B60W 2520/14; B60W 2720/10; B60W 2720/12

(57) ABSTRACT

A reinforcement learning algorithm-based predictive control method for lateral and longitudinal coupled vehicle formation includes S1, combining a 3-DOF vehicle dynamics model that takes into account a nonlinear magic formula tire model with a lane keeping model and establishing a vehicle formation model; S2, constructing a distributed control framework and designing a local predictive controller for each following vehicle based on the vehicle formation model under the control framework; S3, using a reinforcement learning algorithm to solve the optimal control strategy of the local predictive controller, and applying the optimal control strategy to the target following vehicle. The present application completes the lateral and longitudinal coupled modeling of vehicle formation and considers the nonlinear characteristics of tires. In addition, the present application also transforms the global optimization problem of vehicle formation into a local optimization problem of each following vehicle.

### CROSS REFERENCE TO THE RELATED APPLICATIONS

This application is based upon and claims priority to Chinese Patent Application No. 202211087600.7, filed on Sep. 7, 2022, the entire contents of which are incorporated herein by reference.

### TECHNICAL FIELD

The present application belongs to the field of automobile control technology, specifically to a reinforcement learning algorithm-based predictive control method for lateral and longitudinal coupled vehicle formation.

### BACKGROUND

In the past few decades, the exponential growth in the number of vehicles has brought great challenges to energy security and traffic safety. According to the National Highway Traffic Safety Administration, about 84% of traffic accidents are attributed to human errors. Vehicle formation can significantly reduce traffic accidents caused by driver fatigue and mishandling, thereby improving road safety. In addition, vehicle formation (especially heavy truck formation) can reduce air drag between vehicles, resulting in lower emissions, fuel consumption, and increased road capacity. These potential benefits have led to an increased interest among scholars in vehicle formation control.

The research on vehicle formation mainly includes longitudinal control and lateral control, which involve:

The goal of longitudinal control is to align the desired speed of the vehicle and to maintain the desired spacing between neighboring vehicles.

The task of lateral control is to steer the vehicle within the designated lane.

The existing research on vehicle formation control mostly adopts the decoupling control method, where separate lateral and longitudinal controllers are designed to realize lateral lane keeping and longitudinal speed tracking respectively. Specifically, the lateral control methods mainly include PID control, fuzzy control, H¥ robust control, etc., and the longitudinal control methods mainly include sliding mode control, adaptive control, model predictive control, etc.

In summary, although the decoupling strategy has some effectiveness in vehicle formation control, the vehicle system is a non-linear, multi-variable, and strongly coupled system, in the conditions of higher acceleration, greater lateral and longitudinal forces, or lower road adhesion coefficients, the lateral and longitudinal coupling effects become particularly significant. During such conditions, the tracking performance of the decoupling control may decrease, leading to a significant reduction in control accuracy, which may lead to vehicle collisions and failure to achieve formation.

In addition, most of the current research on vehicle formation is based on the assumption of linear tires, which are only applicable within a limited operating range of the vehicle. When the vehicle moves out of the area (such as obstacle avoidance), the nonlinear and lateral and longitudinal coupled effects of the vehicle system become more pronounced, resulting in a mismatch between the decoupling control and emergency control of the vehicle.

### SUMMARY

In light of these challenges raised in the above background technology, the purpose of the present application is to provide a reinforcement learning algorithm-based predictive control method for lateral and longitudinal coupled vehicle formation.

In order to achieve the aforementioned objectives, the present application provides the following technical solution:

A reinforcement learning algorithm-based predictive control method for lateral and longitudinal coupled vehicle formation, including:
S1, combining a 3-degree of freedom (DOF) vehicle dynamics model that takes into account a nonlinear magic formula tire model with a lane keeping model, in order to establish a vehicle formation model

xᵢ(k+1)=f(xᵢ(k),uᵢ(k));

in the formula, xᵢ(k) is a state quantity and uᵢ(k) is an input quantity;
S2, constructing a distributed control framework and designing a local predictive controller for each following vehicle based on the vehicle formation model under the control framework

Jᵢ(xᵢ(k),Uᵢ(k))=Σₗ₌₀^{T}^{ₚ}⁻¹∥xᵢ(k+i)−rᵢ(k+i)∥_{Q}_{ᵢ}²+∥xᵢ(k+i)−\hat{x}ᵢ(k+i)∥_{F}_{ᵢ}²+∥xᵢ(k+i)−\hat{x}ᵢ₋₁(k+i)∥_{G}_{ᵢ}²+∥uᵢ(k+i)∥_{R}_{ᵢ}²

in the formula, k is a current moment, k+i is a first moment in the prediction time domain, xᵢ(•) is a prediction state, rᵢ(•) is an ideal state, \hat{x}ᵢ₋₁(•) and \hat{x}ᵢ(•) represent assumed trajectory states of the vehicle, \hat{x}ᵢ₋(•) is obtained through inter-vehicle communication, Tₚ is a prediction time domain, Qᵢ, Fᵢ, Gᵢ, Rᵢ are the weight matrices;
S3, using a reinforcement learning algorithm to solve the optimal control strategy of the local predictive controller and applying the optimal control strategy to the target following vehicle.

Preferably, the lateral force of the tire in the nonlinear magic formula tire model is calculated by the following magic formula:

Fᵢ^{y}=D sin(C arctan(Bα−E(Bα−arctan Bα)))
in the formula, α is a cornering angle of the tire, and B, C, D, E are simulation parameters.

Preferably, the 3-DOF vehicle dynamics model is expressed as:

$$\text{?} ( {m}_{i} {\dot{v}}_{i}^{x} - {m}_{i} {v}_{i}^{y} {\dot{φ}}_{i} ) = {F}_{i}^{x}$$

$$\text{?} ( {m}_{i} {\dot{v}}_{i}^{y} - {m}_{i} {v}_{i}^{x} {\dot{φ}}_{i} ) = {F}_{i}^{yf} + {F}_{i}^{yr} ;$$

$$\text{?} {I}_{i}^{z} {\ddot{φ}}_{i} = {a}_{i} {F}_{i}^{yf} cos {δ}_{i} - {b}_{i} {F}_{i}^{y r}$$

$$\text{?} \text{indicates text missing or illegible when filed}$$

each parameter in the formula is the parameter of i^{th} vehicle, and
vᵢ^{x},vᵢ^{y},\dot{φ}ᵢ are longitudinal speed, lateral speed, and yaw rate, Fᵢ^{x} is a longitudinal force, Fᵢ^{yf} and Fᵢ^{yr} are the front and rear wheel lateral forces, mᵢ is a vehicle mass, Iᵢ^{z} is a moment of inertia of the vehicle around the z axis, δᵢ is the front wheel angle, aᵢ and bᵢ are the distances from the center of mass to the front and rear axles, respectively.

Preferably, the lane keeping model is expressed as:

$$\text{?} {\dot{e}}_{i}^{p} = {v}_{i}^{x} - {v}_{0}^{x}$$

$$\text{?} {\dot{e}}_{i}^{y} = {v}_{i}^{x} {e}_{i}^{φ} - {v}_{i}^{y} - L {\dot{φ}}_{i}$$

$$\text{?} {\dot{e}}_{i}^{φ} = {\dot{φ}}_{i , des} - {\dot{φ}}_{i}$$

$$\text{?} \text{indicates text missing or illegible when filed}$$

in the formula, \dot{φ}_{i,des} is expected heading angular speed, L is a preview distance, eᵢ^{p} is a longitudinal spacing error, eᵢ^{y} is a lateral position error between the vehicle and the lane line, and eᵢ^{φ} is a heading angle error between the vehicle heading angle and the road tangent.
combining the 3-DOF vehicle dynamics model with the lane keeping model to derive the vehicle formation model:

$$\text{?} {\dot{v}}_{i}^{x} = {v}_{i}^{y} {\dot{φ}}_{i} + \frac{1}{{m}_{i}} {F}_{i}^{x}$$

$$\text{?} {\dot{v}}_{i}^{y} = - {v}_{i}^{x} {\dot{φ}}_{i} + \frac{{F}_{i}^{y f} + {F}_{i}^{y r}}{{m}_{i}}$$

$$\text{?} {\ddot{φ}}_{i} = \frac{1}{{I}_{i}^{z}} ( {a}_{i} {F}_{i}^{y f} - {b}_{i} {F}_{i}^{y r} ) ;$$

$$\text{?} {\dot{e}}_{i}^{p} = {v}_{i}^{x} - {v}_{0}^{x}$$

$$\text{?} {\dot{e}}_{i}^{y} = {v}_{i}^{x} {e}_{i}^{φ} - {v}_{i}^{y} - L {\dot{φ}}_{i}$$

$$\text{?} {\dot{e}}_{i}^{φ} = {\dot{φ}}_{i , des} - {\dot{φ}}_{i}$$

$$\text{?} \text{indicates text missing or illegible when filed}$$

By discretizing the model above and using the state variable xᵢ=[vᵢ^{x} vᵢ^{y} \dot{φ}ᵢ eᵢ^{p} eᵢ^{y} eᵢ^{φ}]^{T} and the control variable uᵢ=[Fᵢ^{x} δᵢ]^{T}, xᵢ(k+1)=f(xᵢ(k),uᵢ(k)) can be obtained.

Preferably, when utilizing the reinforcement learning algorithm to solve the optimal control strategy of the local predictive controller:
constructing and training an actor strategy function neural network to optimize the strategy parameters; specifically, when optimizing the strategy parameters, the actor strategy functional neural network uses a network composed of Tₚ radial basis functions to approximate the Tₚ-step optimal strategy, and the actor strategy functional neural network takes the state s as the input and the action a as the output;
constructing and training a critic value function neural network to evaluate the pros and cons of the current control strategy optimized by the actor strategy function neural network, specifically, when assessing the pros and cons of the current control strategy, the critic value function neural network is evaluated by a network consisting of Tₚ radial basis functions, and the critic value function neural network takes state s and action a as input and state-action value q(s,a) as output;
obtaining the optimal control strategy involves the alternating convergence of the actor strategy function neural network and the critic value function neural network.

Preferably, basis vectors ϕ(x) and ψ(x) in the actor strategy function neural network and the critic value function neural network are both radial basis functions, and

$$\begin{matrix}ϕ ( x ) = ψ ( x ) \\ = {( {exp}^{- {‖ x - {x}_{1} ‖}^{2} / {κ}^{2}} , {exp}^{- {‖ x - {x}_{2} ‖}^{2} / {κ}^{2}} , … {e}^{- {‖ x - {x}_{M} ‖}^{2} / {κ}^{2}} )}^{T} ;\end{matrix}$$

in the formula, κ is set to 1, {xᵢ, i=1, 2, . . . M} as the center of the radial basis function, and M is a number of hidden layers.

Preferably, the center of radial basis function is obtained by normalization:

$${x}_{normalize} = \frac{{x}_{collect} - {x}_{min}}{{x}_{max} - {x}_{min}} ;$$

in the formula, x_{normalize} is normalized data, x_{collect} is collected data, xₘₐₓ and xₘᵢₙ are the maximum and minimum values in the collected data respectively;
the collected data involves a randomly given within the control input range, and the input data and output data of the vehicle formation model are collected by simulation.

Specifically, during the alternating convergence process to obtain the optimal control strategy:
initializing an actor strategy function neural network weight θ and a critic value function neural network weight ω;
obtaining action a by the actor strategy function neural network according to the current state s of the target following vehicle, and acting action a on the target following vehicle to obtain new state s^{c} and instant reward r;
obtaining new action a^{c} by the actor strategy function neural network according to the new state s^{c};
evaluating and scoring action a and action a^{c} by the critic value function neural network to obtain q(s,a) and q(sⁱⁱ,a) and then calculating an error TDerror: TDerror=yᵢ−q(s,a), yᵢ=r+γq(sⁱⁱ,a) between a predicted value q(s,a) and an expected value yᵢ of the critic value function neural network according to the Bellman equation;
using a gradient descent method to minimize the iterative update of the weight 9 and the weight ω, and the optimal control strategy Uᵢ*, L(θ)=q(s,a), L(ω)=½TDerror²;

Preferably, in the predictive time domain, the optimal control strategy Uᵢ* is applied to the target following vehicle through the local predictive controller.

Compared with the existing technology, the present application has the following beneficial effects:
(1) Compared with the traditional decoupling control method, the present application is more in line with the nonlinear, multi-variable, and strong coupling characteristics of the vehicle system, the lateral and longitudinal coupling modeling of the vehicle formation is completed, and the nonlinear characteristics of the tire are considered; In addition, under the framework of distributed model predictive control, a local predictive controller is designed for each following vehicle. This approach transforms the global optimization problem of vehicle formation into a local optimization problem for each following vehicle, which avoids the burden of centralized control.
(2) The reinforcement learning actor-critic algorithm is used to optimize the policy, specifically, the alternating critic training (policy evaluation) and actor training (policy improvement) are used to train the actor network to approach or approximate the optimal control strategy, compared with the common policy-based learning methods, the present application can realize the single-step update of the policy, thereby reducing the number of iterative learning.
(3) The present application uses the hidden layer space composed of radial basis functions to map high-dimensional input data thereby transforming the originally linear inseparable problem into a linearly separable one. This allows for the use of a linear optimization strategy to adjust the weights, resulting in a fast network learning speed and effectively improving the efficiency of solving optimization problems.

### BRIEF DESCRIPTION OF THE DRAWINGS

FIG. 1 is a schematic diagram of the 3-DOF vehicle dynamics model of the present application;

FIG. 2 is a Map table reflecting the relationship curve between the tire cornering angle and the tire lateral force.

FIG. 3 is a control flow chart of the local predictive controller of the present application;

FIG. 4 is a structure diagram of the reinforcement learning algorithm of the present application;

FIG. 5 is a network structure diagram composed of the radial basis function of the present application.

### DETAILED DESCRIPTION OF THE EMBODIMENTS

The technical solution of the embodiment of the present application will be described clearly and completely, combined with the accompanying drawings. Obviously, the described embodiment is only part of the embodiments of the present application, not all of the embodiments. Based on the embodiment in the present application, all other embodiments obtained by ordinary technicians in this field without making creative labor belong to the scope of protection of the present application.

A reinforcement learning algorithm-based predictive control method for lateral and longitudinal coupled vehicle formation, including:

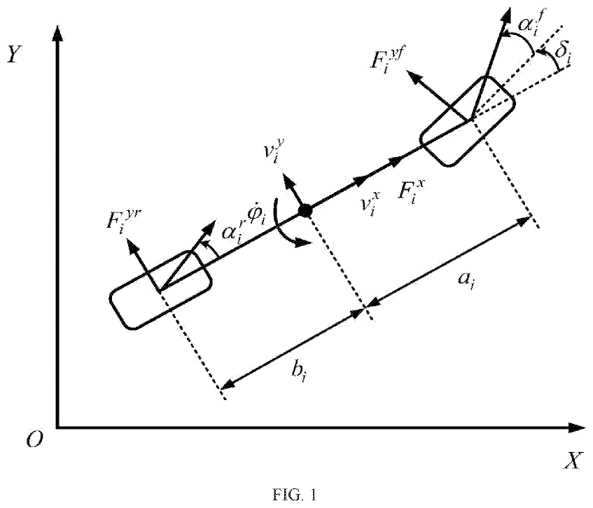

S1, combining the 3-DOF vehicle dynamics model that takes into account the nonlinear magic formula tire model with the lane keeping model, in order to establish the vehicle formation model;
among them:
as shown in FIG. 1, the 3-DOF vehicle dynamics model is expressed as

$$\text{?} ( {m}_{i} {\dot{v}}_{i}^{x} - {m}_{i} {v}_{i}^{y} {\dot{φ}}_{i} ) = {F}_{i}^{x}$$

$$\text{?} ( {m}_{i} {\dot{v}}_{i}^{y} - {m}_{i} {v}_{i}^{x} {\dot{φ}}_{i} ) = {F}_{i}^{yf} + {F}_{i}^{y r} ;$$

$$\text{?} {I}_{i}^{z} {\ddot{φ}}_{i} = {a}_{i} {F}_{i}^{yf} cos {δ}_{i} - {b}_{i} {F}_{i}^{y r}$$

$$\text{?} \text{indicates text missing or illegible when filed}$$

each parameter in the formula is the parameter of i^{th} vehicle, and
vᵢ^{x}, vᵢ^{y}, \dot{φ}ᵢ are longitudinal speed, lateral speed, and yaw rate, Fᵢ^{x} is a longitudinal force, Fᵢ^{yf} and Fᵢ^{yr} are the front and rear wheel lateral forces, mᵢ is a vehicle mass, Iᵢ^{z} is a moment of inertia of the vehicle around the z axis, δᵢ is the front wheel angle, aᵢ and bᵢ are the distances from the center of mass to the front and rear axles, respectively.

The tire lateral force of the tire in the nonlinear magic formula tire model is calculated by the following magic formula:

Fᵢ^{y}=D sin(C arctan(Bα−E(Bα−arctan Bα)))
in the formula, α is a cornering angle of the tire, and B, C, D, E are simulation parameters.

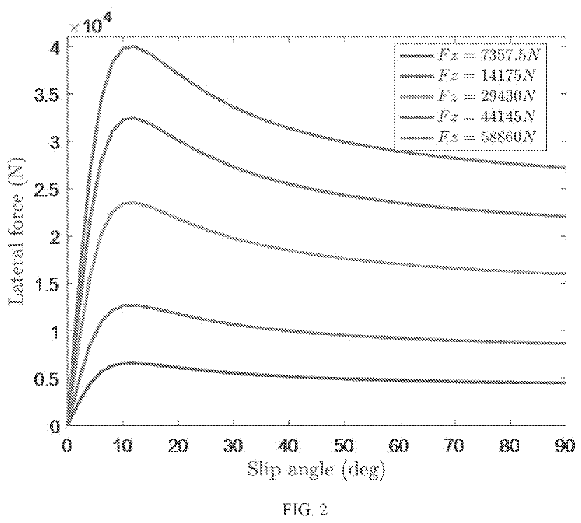

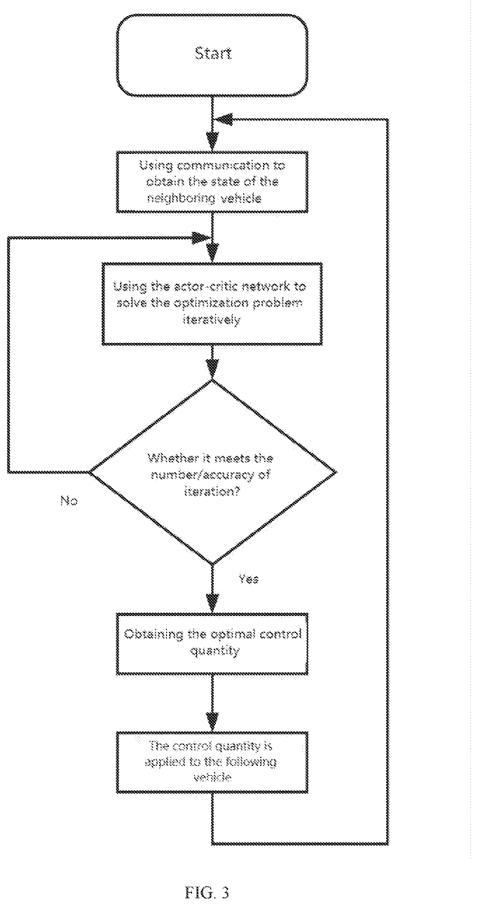

Specifically, when considering the nonlinear magic formula tire model, calculating the longitudinal load of the front and rear tires first, and then obtaining the relationship curve between the tire sideslip angle and the tire lateral force by using the interpolation method with reference to FIG. 2, and then obtaining the parameter B, C, D, E by fitting the above magic formula of the tire.

The lane keeping model is expressed as.

$$\text{?} {\dot{e}}_{i}^{p} = {v}_{i}^{x} - {v}_{0}^{x}$$

$$\text{?} {\dot{e}}_{i}^{y} = {v}_{i}^{x} {e}_{i}^{φ} - {v}_{i}^{y} - L {\dot{φ}}_{i}$$

$$\text{?} {\dot{e}}_{i}^{φ} = {\dot{φ}}_{i , des} - {\dot{φ}}_{i}$$

$$\text{?} \text{indicates text missing or illegible when filed}$$

in the formula, \dot{φ}_{i,des} is expected heading angular speed, L is a preview distance, eᵢ^{p} is a longitudinal spacing error, eᵢ^{y} is a lateral position error between the vehicle and the lane line, and eᵢ^{φ} is a heading angle error between the vehicle heading angle and the road tangent.

In summary, combining the above 3-DOF vehicle dynamics model with the lane keeping model, the vehicle formation model can be obtained as follows;

$$\text{?} {\dot{v}}_{i}^{x} = {v}_{i}^{y} {\dot{φ}}_{i} + \frac{1}{{m}_{i}} {F}_{i}^{x}$$

$$\text{?} {\dot{v}}_{i}^{y} = - {v}_{i}^{x} {\dot{φ}}_{i} + \frac{{F}_{i}^{y f} + {F}_{i}^{y r}}{{m}_{i}}$$

$$\text{?} {\ddot{φ}}_{i} = \frac{1}{{I}_{i}^{z}} ( {a}_{i} {F}_{i}^{y f} - {b}_{i} {F}_{i}^{y r} ) ;$$

$$\text{?} {\dot{e}}_{i}^{p} = {v}_{i}^{x} - {v}_{0}^{x}$$

$$\text{?} {\dot{e}}_{i}^{y} = {v}_{i}^{x} {e}_{i}^{φ} - {v}_{i}^{y} - L {\dot{φ}}_{i}$$

$$\text{?} {\dot{e}}_{i}^{φ} = {\dot{φ}}_{i , des} - {\dot{φ}}_{i}$$

$$\text{?} \text{indicates text missing or illegible when filed}$$

taking the state quantity xᵢ=[vᵢ^{x} vᵢ^{y} \dot{φ}ᵢ eᵢ^{p} eᵢ^{y} eᵢ^{φ}]^{T}, the control quantity uᵢ=[Fᵢ^{x} δᵢ]^{T} and the sampling time Tₛ, the discrete form of the vehicle formation model can be obtained after discretization of the above vehicle formation model: xᵢ(k+1)=f(xᵢ(k),uᵢ(k)); in the formula, xᵢ(k) is the state variable and uᵢ(k) is the input variable.
S2, constructing a distributed control framework and designing a local predictive controller for each following vehicle based on the vehicle formation model under the control framework

Jᵢ(xᵢ(k),Uᵢ(k))=Σₗ₌₀^{T}^{ₚ}⁻¹∥xᵢ(k+i)−rᵢ(k+i)∥_{Q}_{ᵢ}²+∥xᵢ(k+i)−\hat{x}ᵢ(k+i)∥_{F}_{ᵢ}²+∥xᵢ(k+i)−\hat{x}ᵢ₋₁(k+i)∥_{G}_{ᵢ}²+∥uᵢ(k+i)∥_{R}_{ᵢ}²

in the formula, k is a current moment, k+i is a first moment in the prediction time domain, xᵢ(•) is a prediction state, rᵢ(•) is an ideal state, \hat{x}ᵢ₋₁(•) and \hat{x}ᵢ(•) represent assumed trajectory states of the vehicle, \hat{x}ᵢ₋(•) is obtained through inter-vehicle communication, Tₚ is a prediction time domain, Qᵢ, Fᵢ, Gᵢ, Rᵢ are the weight matrices; where the assumed input of each vehicle is defined as follows:

$${\hat{u}}_{i} ( k + j \vert k + 1 ) = \begin{matrix}\text{?} {u}_{i}^{*} ( k + j \vert k ) , j = 0 , … {T}_{p} - 2 \\ \text{?} 0 , j = {T}_{p} - 1\end{matrix} ;$$

$$\text{?} \text{indicates text missing or illegible when filed}$$

It is assumed that the trajectory can be calculated from the assumed input:

$$\text{?} {\hat{x}}_{i} ( k + j + 1 \vert k + 1 ) = f ( {\hat{x}}_{i} ( k + j \vert k + 1 ) , {\hat{u}}_{i} ( k + j \vert k + 1 ) )$$

$$\text{?} {\hat{x}}_{i} ( k + 1 \vert k + 1 ) = {x}_{i}^{*} ( k + 1 \vert k )$$

$$\text{?} \text{indicates text missing or illegible when filed}$$

S3, using a reinforcement learning algorithm to solve the optimal control strategy of the local predictive controller and applying the optimal control strategy to the target following vehicle through the local predictive controller.

(31) Constructing the actor strategy function neural network and the critic value function neural network.

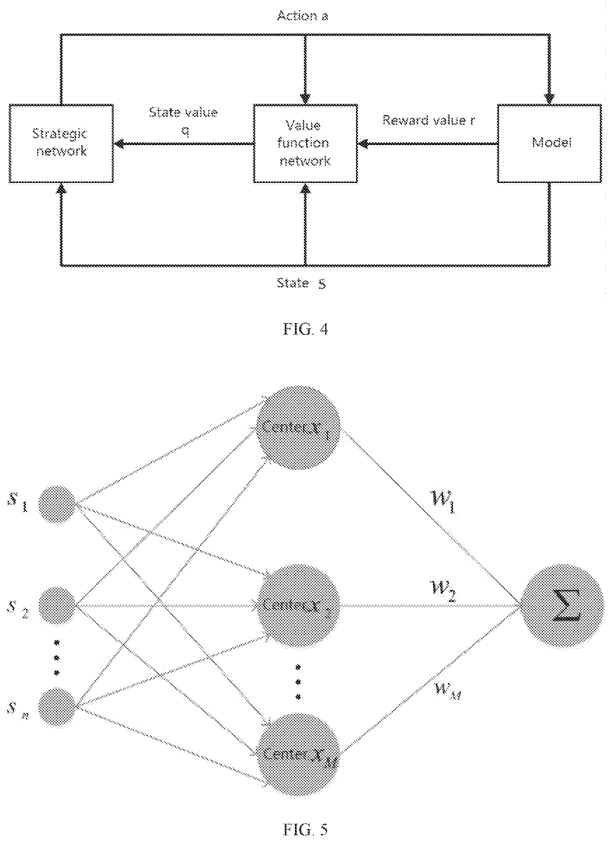

Specifically, combined with the structure shown in FIG. 4, the actor strategy function neural network and the critic value function neural network are set as follows:

The actor strategy function neural network uses a network consisting of Tₚ radial basis functions to approximate the Tₚ-step optimal strategy;
evaluating the critical value function neural network by a network consisting of Tₚ radial basis functions;
the network structure composed of Tₚ radial basis functions is shown in FIG. 5, in the approximation optimal strategy, the actor strategy function neural network takes state s as input and action a as output; in the evaluation, the critic value function neural network takes state s and action a as input and state-action value q(s,a) as output.

Preferably, the basis vectors ϕ(x) and ψ(x) in the actor strategy function neural network and the critic value function neural network are radial basis functions, and

$$\begin{matrix}ϕ ( x ) = ψ ( x ) \\ = {( {exp}^{- {‖ x - {x}_{1} ‖}^{2} / {κ}^{2}} , {exp}^{- {‖ x - {x}_{2} ‖}^{2} / {κ}^{2}} , … {e}^{- {‖ x - {x}_{M} ‖}^{2} / {κ}^{2}} )}^{T}\end{matrix}$$

In the formula, x is set to 1, {xᵢ=1, 2, . . . M} as the center of the radial basis function, and M is the number of hidden layers.

The center of radial basis function is obtained by normalization:

$${x}_{normalize} = \frac{{x}_{collect} - {x}_{min}}{{x}_{max} - {x}_{min}} ;$$

in the formula, x_{normalize} is normalized data, x_{collect} is collected data, xₘₐₓ and xₘᵢₙ are the maximum and minimum values in the collected data respectively; specifically, the collected data involves a randomly given within the control input range, and the input data and output data of the vehicle formation model are collected by simulation.

(32) Training actor strategy function neural network and critic value function neural network.

initializing the actor strategy function neural network weight θ and the critic value function neural network weight ω;

obtaining action a by the actor strategy function neural network according to the current state s of the target following vehicle, and acting action a on the target following vehicle to obtain new state s^{c} and instant reward r;
obtaining new action a^{c} by the actor strategy function neural network according to the new state s^{c};
evaluating and scoring action a and action a^{c} by the critic value function neural network to obtain q(s,a) and q(sⁱⁱ,a) and then calculating an error TDerror: TDerror=yᵢ−q(s,a), yᵢ=r+γq(sⁱⁱ,a) between a predicted value q(s,a) and an expected value yᵢ of the critic value function neural network according to the Bellman equation;

in order to minimize the value function obtained by the action output of the actor strategy function neural network, taking the value function q(s,a) as the loss function L(θ) of the actor strategy function neural network, that is, L(θ)=q(s,a), and using the gradient descent method to iteratively update the weight θ; in order to make the score of the critic value function neural network more accurate, taking the loss function L(ω)=½TDerror² of the critic value function neural network, and updating the weight ω iteratively by the gradient descent method; specifically, when the number of iterations or the accuracy meets the preset conditions, the optimal control strategy Uᵢ* is obtained.

(33) Using the above actor strategy function neural network and critic value function neural network to solve the optimal control strategy of the local predictive controller, and the optimal control strategy Uᵢ* solved in the prediction time domain acts on the target following vehicle through the local predictive controller.

Although the embodiment of the present application has been presented and described, it is understandable to ordinary technicians in the field that these embodiments can be varied, modified, replaced, and amended without departing from the principles and spirit of the present application, Therefore, the scope of the present application is limited by the accompanying claims and their equivalents.

What is claimed is:

1. A reinforcement learning algorithm-based predictive control method for a lateral and longitudinal coupled vehicle formation, comprising:
S1, combining a 3-degree of freedom (DOF) vehicle dynamics model with a lane keeping model to establish a vehicle formation model, wherein the 3-DOF vehicle dynamics model takes into account a nonlinear magic formula tire model;
xᵢ(k+1)=f(xᵢ(k),uᵢ(k));
wherein xᵢ(k) is a state quantity and uᵢ(k) is an input quantity;
S2, constructing a distributed control framework and designing a local predictive controller for each target following vehicle based on the vehicle formation model under the distributed control framework;
$${J}_{i} ( {x}_{i} ( k ) , {U}_{i} ( k ) ) = {\sum }_{i = 0}^{{T}_{p} - 1} {‖ {x}_{i} ( k + i ) - {r}_{i} ( k + i ) ‖}_{{Q}_{i}}^{2} + {‖ {x}_{i} ( k + i ) - {\hat{x}}_{i} ( k + i ) ‖}_{{F}_{i}}^{2} + {‖ {x}_{i} ( k + i ) - {\hat{x}}_{i - 1} ( k + i ) ‖}_{{G}_{i}}^{2} + {‖ {u}_{i} ( k + i ) ‖}_{{R}_{i}}^{2}$$
wherein k is a current moment, k+1 is a first moment in a prediction time domain, xᵢ(•) is a prediction state, rᵢ(•) is an ideal state, \hat{x}ᵢ₋₁(•) and \hat{x}ᵢ(•) represent assumed trajectory states of the vehicle, \hat{x}ᵢ₋(•) is obtained through an inter-vehicle communication, Tₚ is a prediction time domain, Qᵢ, Fᵢ, Gᵢ, Rᵢ are weight matrices;
S3, using a reinforcement learning algorithm to solve an optimal control strategy of the local predictive controller and applying the optimal control strategy to the each target following vehicle.

2. The reinforcement learning algorithm-based predictive control method for the lateral and longitudinal coupled vehicle formation according to claim 1, wherein a lateral force of a tire in the nonlinear magic formula tire model is calculated by the following magic formula:
Fᵢ^{y}=D sin(C arctan(Bα−E(Bα−arctan Bα)))
wherein α is a cornering angle of the tire, and B, C, D, E are simulation parameters.

3. The reinforcement learning algorithm-based predictive control method for the lateral and longitudinal coupled vehicle formation according to claim 1, wherein the 3-DOF vehicle dynamics model is expressed by the following formula:
$$\text{?} ( {m}_{i} {\dot{v}}_{i}^{x} - {m}_{i} {v}_{i}^{y} {\dot{φ}}_{i} ) = {F}_{i}^{x}$$
$$\text{?} ( {m}_{i} {\dot{v}}_{i}^{y} - {m}_{i} {v}_{i}^{x} {\dot{φ}}_{i} ) = {F}_{i}^{yf} + {F}_{i}^{y r} ;$$
$$\text{?} {I}_{i}^{z} {\ddot{φ}}_{i} = {a}_{i} {F}_{i}^{yf} cos {δ}_{i} - {b}_{i} {F}_{i}^{y r}$$
$$\text{?} \text{indicates text missing or illegible when filed}$$
each parameter in the formula is a parameter of an i^{th} vehicle, and
vᵢ^{x}, vᵢ^{y}, \dot{φ}ᵢ are longitudinal speed, lateral speed, and yaw rate, Fᵢ^{x} is a longitudinal force, Fᵢ^{yf} and Fᵢ^{yr} are the front and rear wheel lateral forces, respectively, mᵢ is a vehicle mass, Iᵢ^{z} is a moment of inertia of the 3-DOF vehicle dynamics around the z axis, δᵢ is the front wheel angle, aᵢ and bᵢ are a distance from the center of mass to a front axle and a distance from the mass center to a rear axle, respectively.

4. The reinforcement learning algorithm-based predictive control method for the lateral and longitudinal coupled vehicle formation according to claim 3, wherein the lane keeping model is expressed as:
$$\text{?} {\dot{e}}_{i}^{p} = {v}_{i}^{x} - {v}_{0}^{x}$$
$$\text{?} {\dot{e}}_{i}^{y} = {v}_{i}^{x} {e}_{i}^{φ} - {v}_{i}^{y} - L {\dot{φ}}_{i}$$
$$\text{?} {\dot{e}}_{i}^{φ} = {\dot{φ}}_{i , des} - {\dot{φ}}_{i}$$
$$\text{?} \text{indicates text missing or illegible when filed}$$
wherein \dot{φ}_{i,des} is an expected heading angular speed, L is a preview distance, eᵢ^{p} is a longitudinal spacing error, eᵢ^{y} is a lateral position error between the 3-DOF vehicle dynamics model and a lane line of the lane keeping model, and eᵢ^{φ} is a heading angle error between a vehicle heading angle and a road tangent.

5. The reinforcement learning algorithm-based predictive control method for the lateral and longitudinal coupled vehicle formation according to claim 1, wherein when utilizing the reinforcement learning algorithm to solve the optimal control strategy of the local predictive controller:
constructing and training an actor strategy function neural network to optimize strategy parameters;
constructing and training a critic value function neural network to evaluate a pros and a cons of a current control strategy optimized by the actor strategy function neural network;
obtaining the optimal control strategy according to an alternating convergence of the actor strategy function neural network and the critic value function neural network.

6. The reinforcement learning algorithm-based predictive control method for the lateral and longitudinal coupled vehicle formation according to claim 5, wherein when optimizing the strategy parameters, the actor strategy functional neural network uses a network composed of Tₚ radial basis functions to approximate a Tₚ-step optimal strategy and takes a state s as a first input and an action a as a first output;
when assessing the pros and the cons of the current control strategy, the critic value function neural network is evaluated by the network composed of the Tₚ radial basis functions and takes the state s and the action a as a second input and a predicted value q(s,a) as a second output.

7. The reinforcement learning algorithm-based predictive control method for the lateral and longitudinal coupled vehicle formation according to claim 6, wherein basis vectors ϕ(x) and ψ(x) in the actor strategy function neural network and the critic value function neural network are the radial basis functions, and
$$\begin{matrix}ϕ ( x ) = ψ ( x ) \\ = {( {exp}^{- {‖ x - {x}_{1} ‖}^{2} / {κ}^{2}} , {exp}^{- {‖ x - {x}_{2} ‖}^{2} / {κ}^{2}} , … {e}^{- {‖ x - {x}_{M} ‖}^{2} / {κ}^{2}} )}^{T}\end{matrix} ;$$
wherein κ is set to 1, {xᵢ, i=1, 2, . . . M} is a center of the radial basis functions, and M is a number of hidden layers.

8. The reinforcement learning algorithm-based predictive control method for the lateral and longitudinal coupled vehicle formation according to claim 7, wherein the center of the radial basis functions is obtained by a normalization:
$${x}_{normalize} = \frac{{x}_{collect} - {x}_{min}}{{x}_{max} - {x}_{min}} ;$$
wherein x_{normalize} is a normalized data, x_{collect} is a collected data, xₘₐₓ and xₘᵢₙ are a maximum value and a minimum value in the collected data respectively;
the collected data involves a randomly given within a control input range, and an input data and an output data of the vehicle formation model are collected by a simulation.

9. The reinforcement learning algorithm-based predictive control method for the lateral and longitudinal coupled vehicle formation according to claim 8, wherein the optimal control strategy is obtained through the alternating convergence;
initializing an actor strategy function neural network weight 9 and a critic value function neural network weight ω;
obtaining the action a by the actor strategy function neural network according to a current state s of the each target following vehicle, and acting the action a on the each target following vehicle to obtain a state s^{c} and an instant reward r;
obtaining an action a^{c} by the actor strategy function neural network according to the state s^{c};
evaluating and scoring the action a and the action a^{c} by the critic value function neural network to obtain the predicted value q(s,a) and a predicted value q(sⁱⁱ,a) and then calculating an error TDerror: TDerror=yᵢ−q(s,a), yᵢ=r+γq(sⁱⁱ,a) between the predicted value q(s,a) and an expected value yᵢ of the critic value function neural network according to a Bellman equation;
using a gradient descent method to minimize an iterative update of the actor strategy function neural network weight θ and the critic value function neural network weight ω to obtain the optimal control strategy Uᵢ*, L(θ)=q(s,a), L(ω)=½TDerror².

10. The reinforcement learning algorithm-based predictive control method for the lateral and longitudinal coupled vehicle formation according to claim 8, wherein in the prediction time domain, the optimal control strategy Uᵢ* is applied to the each target following vehicle through the local predictive controller.
